(19) United States
(12) Patent Application Publication
(10) Pub. No.: US 2007/0040263 A1
(43) Pub. Date: Feb. 22, 2007

(54) Green data center and virtual power plant

(76) Inventor: Timothy D. Towada, Elmhurst, IL (US)

Correspondence Address: DYKEMA GOSSETT PLLC, 10 S. WACKER DR., STE. 2300, CHICAGO, IL, 60606, US

(21) Appl. No.: 11/291,077

(22) Filed: Nov. 30, 2005

Related U.S. Application Data
(60) Provisional application No. 60/631,632, filed on Nov. 30, 2004.

(51) Int. Cl. H01L 23/12

(52) U.S. Cl. 257/700

(57) ABSTRACT

A power system for cooling backup computer storage facilities having eight independent levels of redundancy for the power supply to allow the storage facility to survive even extreme and debilitating events and having redundant communications. If power from the existing gas or electric grid is lost, a series of back-up energy sources provide energy to run the micro-turbines and generate the power to run the servers and the HVAC system that cools the servers. In the event that the existing power grid is interrupted, the redundant power supplies are automatically engaged without disruption of the load. If the existing gas and/or electric power grids are disrupted, the storage facility is powered/cooled by a micro-grid having its own independent redundant sources of power.

The present invention claims the benefit of U.S. Provisional Application No. 60/631632 filed 30 Nov. 2005.

### BACKGROUND OF THE INVENTION

1. Field of the Invention

The present invention relates to power plants, more specifically it relates to redundant power systems for cooling backup computer storage facilities.

2. Description of Related Art

More and more records are in electronic form. For example, most financial and medical records are maintained in electronic form. Because critical data in maintained in electronic form, there is a need for back-up systems, disaster recovery systems, and redundancies to protect the integrity of the hardware that maintains the records as well as the back-up records/data itself. There is also a need to access the backup system and data. Thus, there must be redundant power supplies to the servers, the chillers that cool the servers and there must be and redundancy of communication so that the data can be accessed.

Early computer back-up power systems utilized internal uninterruptible power supplies (UPS) such as a battery back up and/or a generating systems comprising a combustion engine driving an electrical generator, commonly referred to as a “genset”. These prior art back-up power supplies provided a reliable platform for batch computer transactions. The weak link in these systems was the computer.

UPS devices come in two forms: online and standby. A standby device kicks in only when the power goes down. It must switch to battery power fast enough to keep the computer running during an outage. An online device constantly provides a source of power to the computer, for example a battery. If the outside source of power dies, the battery back-up within the unit continue to supply the computer with power.

Later back-up power supplies utilized UPS and gensets having hardened electrical systems. The hardened electrical systems were needed to keep pace with the increased computer reliability. Today, most computing is continuous. Primary power supplies allow for continuous computing. However, back-up power supplies are still batch. There is a need for a back-up power supply that can provide for continuous computing. A UPS provides electrical power to computers or other devices during a power outage and can be one of the following: A battery system, a rotary UPS that uses the inertia of a large flywheel to carry the computer system through brief outages, or a internal combustion motors that run AC generators.

Typically electronic data is protected by maintaining a system back up. The data may be maintained on alternative servers at a disaster recovery site, other location or even in the same location as the primary server. The data may also be stored on external media. In addition having back-up data stored in an accessible manner, it is necessary to have back-up power to run the system so that the data is accessible. There is a need for short-term back up power to get the system up and running and/or to allow the system to continue to run during short power outages. There is a need for intermediate-term back-up power and for long-term back-up power supplies to allow access to the data in the event the primary power system in out of commission. Because there is a need for short-, intermediate- and long-term back-up power, there is a need for several redundancies in the power system. There is also a need for redundancies of communications and for a secure system.

The Department of Energy (DOE) recognized the importance of and reliance of the grid on critical data operations. In 2002, the DOE commissioned a study on how distributed generation (DG) could be utilized to improve power quality and reliability to data centers. The most common technology selected to provide distributed power generation is the micro-turbine. Fuel cells may also be used, however currently they are cost prohibitive.

### SUMMARY OF THE INVENTION

The present invention is a power system for cooling backup computer storage facilities having eight independent levels of redundancy for the power supply to allow the storage facility to survive even extreme and debilitating events. The inventive power system also has redundant communications.

The back-up computer storage facility is cooled and the servers powered by power supplied by the existing gas grid. If power from the gas grid is lost, a series of back-up energy sources provide energy to run the micro-turbines and generate the power to run the servers. The back-up energy sources also supply power to the HVAC system that cools the servers.

In the event that the gas grid is interrupted, the system is designed so that electric grid is automatically engaged without disruption of the load. Alternatively, the servers and chillers may be initially powered by the electric grid.

If the existing gas and/or electric power grids are disrupted, the storage facility is powered/cooled by a micro-grid having its own independent redundant sources of power. A primary flywheel is located internal to the igloo. The igloo also contains a redundant flywheel. The flywheels supply energy for very brief period of time. The electric grid provides the next level of redundancy. The next level of redundancy is provided by a diesel genset located outside the igloo. The next level of redundancy is provided by a redundant micro-turbine. The redundant micro-turbine is the micro turbine of the first adjacent igloo. The diesel standby generator of the first adjacent igloo provides the next level of redundancy. The diesel generator of the second adjacent igloo provides the next level of redundancy.

The final level of redundancy is automatically activated when all the prior levels have fail or it can be activated manually. A plurality of igloos is connected into an island micro grid. The igloos utilize internally stored energy supplies, such as diesel and liquid propane (LP) fuel. The island is virtual power plant (VPP). The VPP manages, monitors, and controls all power generation operations. The power generation of all igloos in an island is synchronized via redundant communication paths including fiber optic communications, microwave and/or satellite communication systems.

Because the igloos primary power source is the natural gas grid, the inventive system is environmentally friendly using less energy and using it in a more efficient energy than the electric grid that generates electricity using fossil fuels.

In addition to needing the ability to store and maintain the data in the event of a power outage, there must be a way to access that data. Thus, the system provides redundant communications. The redundant communications comprise fiber optic connections, satellite communication, and microwave communication.

The inventive system is also a secure system to protect critical data.

### BRIEF DESCRIPTION OF THE FIGURES

FIG. 1 is a block diagram of a prior art data center.

FIG. 2 is a block diagram of a green data center.

FIG. 3 is a block diagram of the inventive a power system.

FIG. 4 is a floor plan of a power igloo.

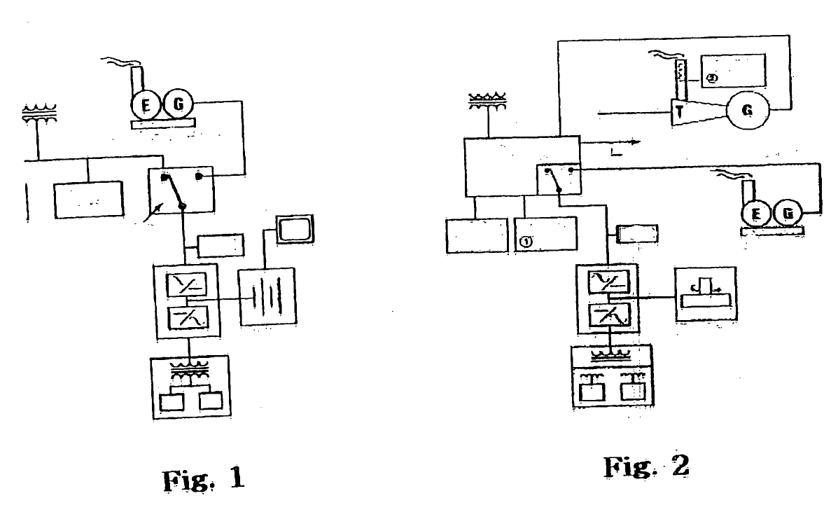

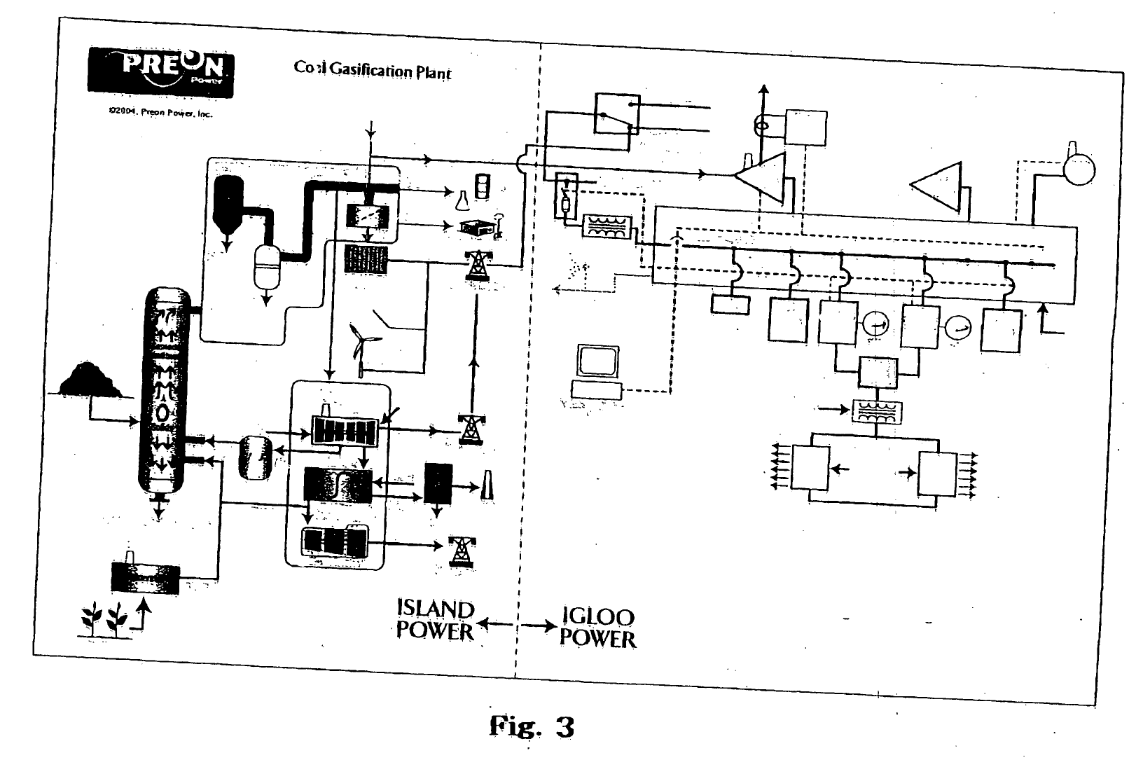

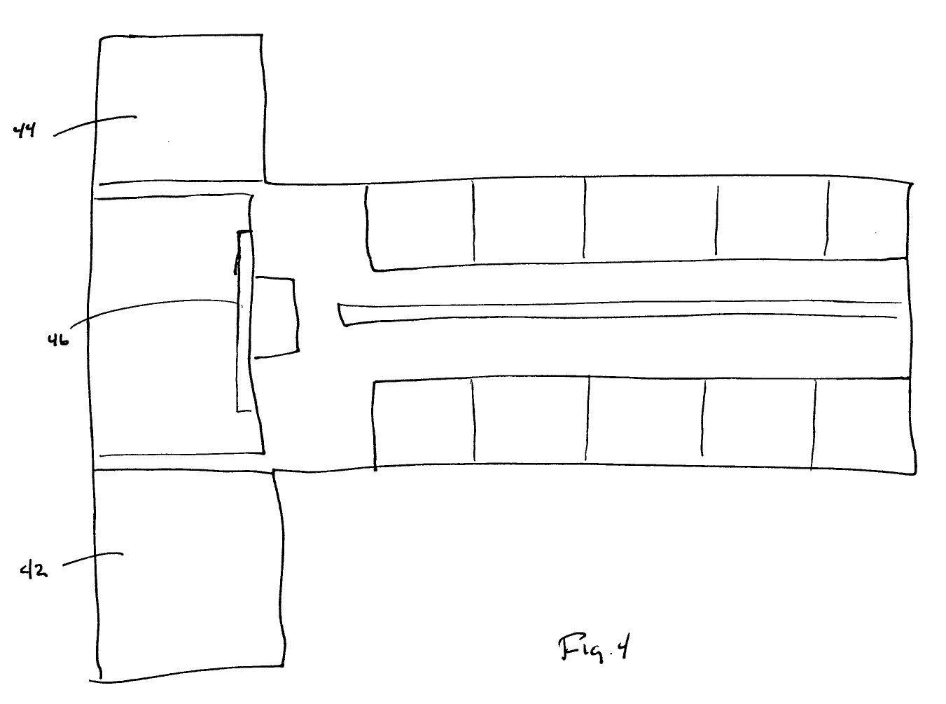

### DETAILED DESCRIPTION OF THE INVENTION

The present invention is a power system for cooling backup computer storage facilities having eight independent levels of redundancy for the power supply to allow the storage facility to survive extreme events that would otherwise incapacitate the system. The inventive power system also has redundant communications. The inventive system is also preferably a secure system that is located at a secure facility.

Back-up computer storage facility is cooled and the servers powered by power 30 supplied by the existing gas grid. The natural gas grid provides gas the micro-turbines to generate power to run the servers and the HVAC system. It is preferable that the primary power source for the system be the existing gas grid. The natural gas grid is the preferred primary power source because the network is buried underground and, thus, is less susceptible to damage. Further, gas outages are less common the electric outages. While the gas grid is the preferred primary source, the electric grid could be the primary power source.

If the power is lost, a series of back-up energy sources provide energy to run the micro-turbines and generate the power to run the servers. The back-up energy sources also supply power to the HVAC system that cools the servers. In the event that the gas grid is interrupted, the system is designed so that electric grid is automatically engaged without disruption of the load. Alternatively, the servers and chillers may be initially powered by the electric grid. The natural gas grid provides gas to micro-turbines to generate the power to run the servers and the HVAC system.

When the primary power source fails, the facility is powered/cooled by a micro-grid having its own independent redundant sources of power. A primary flywheel is located internal to the igloo. If the energy supplied by the gas grid is interrupted, the primary flywheel carries a load, preferably 80 kV, to the uninterruptible power supply for a short period of time. Preferably, the load is carried for about 35 seconds. If the primary flywheel is unable to supply power or has supplied power for the requisite period of time, the secondary/redundant flywheel, also located in the igloo, carries a load to the uninterruptible power supply for a short period of time. Preferably, the load is carried for about 35 seconds. Preferably, the load is about 80 kV. Flywheels are preferable to battery back up as they are environmentally friendlier and there is no hazardous material to be disposed of. Preferably, the data center reduces the heat load and the amount of raw materials utilized to be as environmentally friendly as possible.

If the secondary flywheel fails or has carried the load for its short period of time, the third level of redundancy is activated. The electric grid provides the third level of redundancy. The electric grid is always connected to the power generated by the micro-turbines. An outage of the gas grid and flywheels/UPS has no impact on the power to the load. The electric grid instantly provides power to the system.

The fourth level of redundancy is provided by a diesel genset located outside the igloo. The standby diesel genset is automatically activated if the electric grid is out or if the flywheels are utilized for more than a specified period of time. Preferably, the diesel genset is activated if the electric grid is out for more than 2 seconds or if a flywheel is in use for more than 8 seconds.

The fifth level of redundancy is provided by a redundant micro-turbine. The redundant micro-turbine is the micro-turbine of the first adjacent igloo. The redundant micro-turbine of the adjacent igloo is automatically engaged in synch and utilizes natural gas if available.

The sixth level of redundancy is provided by the diesel genset of the first adjacent igloo. If the igloo cannot be supported by the electric grid or the gas grid utilizing the micro-turbine of the adjacent igloo, a first redundant diesel genset is energized. The first redundant diesel genset is the diesel genset of the first adjacent igloo.

The seventh level of redundancy is provided by the second redundant diesel genset. The second redundant diesel genset is the diesel genset of the second adjacent igloo. The second redundant diesel genset is energized if the first redundant diesel genset does not fire up.

The eighth level of redundancy can be automatically activated when all the prior levels have fail or it can be activated manually. In the event both natural gas and the electric grids are down, all the igloos will be running off of their respective diesel gensets. When all the gensets are energized, all igloos automatically morph into an island. The igloos form a micro grid island where all the igloos are in synch and a large central genset fueled by liquid propane (LP) or diesel supports the entire island. The LP and/or diesel fuel is stored in a secure facility at or near the igloos. Further, while it is preferable that all the igloos at a facility be part of the island, it is not necessary. More than one island can exist in a facility.

When island mode is activated, the igloos are automatically disconnected from the existing gas and electric grids. The island is powered by one or more central power plant, preferably internal combustion engines powered by diesel and/or LP gas.

The island is virtual power plant (VPP). The VPP manages, monitors, and controls all power generation operations. The green data center works in conjunction with the Internet to form the VPP. Paralleling gear utilizing solid-state chips is preferably networked to other data centers or facilities via the Internet. A user can aggregate and manage power generation for maximum reliability and to achieve economic efficiencies.

The power generation of all igloos in an island is synchronized via three independent, redundant communication media including fiber optic communications, microwave and/or satellite communication systems. In the event that fiber optic and the microwave communications are disrupted and the integrity of the island cannot be verified, the satellite will give a final signal to the igloos of the island to disengage from the island micro-grid and run autonomously in ultimate island mode. In ultimate island mode each igloo runs independently.

Once natural gas and/or electric grids and communications are stabilized and secured the VPPs will automatically and sequentially return to normal operation.

Optionally, one or more level of redundancy can be eliminated. For example, the system could eliminate the second redundant diesel genset. While the above order is preferably, it is not necessary to activate the levels of redundancy in this order. For example, an effective redundant system could activate a nearby genset prior to the genset adjacent to the affected igloo. Additional levels of redundancy could be provided.

Because the igloos primary power source is the natural gas grid, the inventive system is environmentally friendly using less energy and using it in a more efficient energy than the electric grid that generates electricity using fossil fuels. In addition, because the first and second levels of redundancy use flywheels instead of batteries, the VPP is more environmentally friendly than prior art back-up systems.

In addition to needing to be able store in the event of a power outage or disaster, there must be a way to maintain the integrity of the data and also to access that data. Thus, the system provides redundant communications. The redundant communications comprise fiber optic connections, satellite communication, and microwave communication.

There is preferably physical security at the facility to protect the servers and infrastructure at the data center or facility. The facility and/or the igloos themselves preferably have bio-hand readers, armed or unarmed security patrols, and forward-looking infrared detection systems. The igloos themselves are preferably made of 24-inch thick reinforced concrete and have 6-inch steel blast doors. The igloos are preferably each placed on 1-acre. Additionally, because the electronic data may be of a critical or sensitive nature there is information security to protect the data. The igloos are preferably climate controlled, have dual data feeds, controlled access and 24-hour monitoring and support.

1. A power system for cooling a backup computer storage facility having a plurality of independent levels of redundancy for the power supply comprising:
an igloo housing
at least one back-up computer server;
at least one micro-turbine to generate power to run the at least one server;
HVAC equipment to cool the at least one server; and
a primary power source to power the at least one micro-turbine and HVAC equipment; and
a plurality of independent back-up power sources.
The power system of claim 1 wherein the primary power source is an existing natural gas grid.

2. The power system of claim 1 wherein the existing electric grid is the primary power source.

3. The power system of claim 1 wherein the back-up power supplies are automatically engaged.

4. The power system of claim 1 wherein when the primary power source fails, the facility is powered/cooled by a micro-grid having its own independent redundant sources of power.

5. The power system of claim 5 wherein at least one of the independent back-up power sources is a primary flywheel located internal to the igloo wherein if the energy supplied by the gas grid is interrupted, the primary flywheel carries the load.

6. The power supply of claim 6 at least one of the independent back-up power sources is a secondary/redundant flywheel, located in the igloo, wherein if the primary flywheel is unable to supply power or has supplied power for a primary period of time, the secondary/redundant flywheel a carries the load for a secondary period of time.

7. The power supply of claim 7 at least one of the independent back-up power sources is an existing electric grid wherein if the secondary flywheel fails or has carried the load for the short period of time, the electric grid carries the load.

8. The power supply of claim 1 wherein the electric grid is always connected to the micro-turbines and the HVAC.

9. The power supply of claim 8 at least one of the independent back-up power sources is a diesel genset located outside the igloo wherein the diesel genset is automatically activated if the electric grid is out or if the primary and secondary flywheels are utilized for more the primary and secondary periods of time.

10. The power supply of claim 10 wherein the diesel genset is activated if the electric grid is out for more than 2 seconds or if the primary or secondary flywheel is in use for more than 8 seconds.

11. The power supply of claim 10 wherein the igloo is connected to at least a first adjacent igloo an the at least one of the independent back-up power sources is a first redundant micro-turbine located in the first adjacent igloo wherein the redundant micro-turbine of the first adjacent igloo is automatically engaged in synch with the micro-turbine.

12. The power supply of claim 11 wherein the first redundant micro-turbine utilizes the natural gas grid if available.

13. The power supply of claim 11 wherein the at least one of the independent back-up power sources is a first redundant diesel genset of the first adjacent igloo and the first redundant diesel genset is energized if the igloo cannot be supported by the electric grid or the gas grid or the first redundant micro-turbine.

14. The power supply of claim 13 wherein the igloo is connected to at least a second adjacent igloo and at least one of the independent back-up power sources is a second redundant diesel genset, said second redundant diesel genset is located in the second adjacent igloo.

15. The power supply of claim 14 wherein the second redundant diesel genset is energized if the first redundant diesel genset does not fire up.

16. The power supply of claim 14 wherein the igloo is connected to a plurtality of igloos and all igloos are running off of their respective diesel gensets.

17. The power supply of claim 16 wherein the igloos form a micro grid island where all the igloos are in synch and a large central genset supports the entire island.

18. The power supply of claim 17 wherein the igloos are automatically disconnected from the existing gas and electric grids.

19. The power supply of claim 18 wherein the igloos are synchronized by one or more independent communication media.

20. The power supply of claim 19 wherein the communication media comprisises fiber optic communications, microwave and/or satellite communication systems.
